(19) United States
(12) Patent Application Publication
(10) Pub. No.: US 2026/0190548 A1
(43) Pub. Date: Jul. 2, 2026

(54) DISPLAY APPARATUS

(71) Applicant: LG Display Co., Ltd., Seoul (KR)

(72) Inventors: Hyeonho SON, Goyang-si (KR); Eunjeong SHIN, Paju-si (KR); Hyungju PARK, Goyang-si (KR); Jinwoo PARK, Goyang-si (KR); Taesung LEE, Seoul (KR)

(73) Assignee: LG Display Co., Ltd., Seoul (KR)

(21) Appl. No.: 19/425,426

(22) Filed: Dec. 18, 2025

(30) Foreign Application Priority Data
Dec. 30, 2024 (KR) 10-2024-0200898

(51) Int. Cl. H10H 20/821; H10H 20/832; H10H 29/24

(52) U.S. Cl. CPC H10H 20/821; H10H 20/832; H10H 29/24

(57) ABSTRACT

The present disclosure relates to a display apparatus which resolves spot defects caused by the nonuniformity of luminous wavelength distribution of a main light-emitting element and a redundancy light-emitting element within one pixel and a poor viewing angle due to a difference in brightness. To achieve this, the display apparatus of the present disclosure may have a structure in which a redundancy light-emitting element is disposed after being inverted with respect to a main light-emitting element and mesa angles of light-emitting layers of the main light-emitting element and the redundancy light-emitting element are formed differently. Accordingly, in the display apparatus according to the present disclosure, the brightness and wavelength distributions for the main light-emitting element and the redundancy light-emitting element within one pixel can be uniformly distributed without being biased to one side.

### CROSS-REFERENCE TO RELATED APPLICATION

Pursuant to 35 U.S.C. § 119(a), this application claims the benefit of an earlier filing date and right of priority to Korean Patent Application No. 10-2024-0200898, filed Dec. 30, 2024, in the Korean Intellectual Property Office, the contents of which are incorporated by reference herein in their entirety.

### BACKGROUND

### Technical Field

The present disclosure relates to a display apparatus, and more specifically, to a display apparatus using a micro light-emitting diode (LED).

### Description of the Related Art

Recently, display apparatuses including a light-emitting diode (LED) have been attracting attention as next-generation display apparatuses. Since an LED is formed of an inorganic material rather than an organic material, the display apparatuses including the LED have a faster turn-on speed, better luminous efficiency, and higher luminance images than LCD apparatuses or OLED display apparatuses.

In the case of these LEDs, a main LEDs and a redundancy LED on a chip on wafer CoW are transferred onto a panel three times every one block for each color through a chip on donor CoD during transfer as a dual chip.

However, in a front of screen (FOS) inspection after transfer, there is a problem that the luminous wavelength distribution of the main LED and the redundancy LED within the dual chip is biased to one side, or a viewing angle is poor due to a difference in brightness between left and right LEDs.

### BRIEF SUMMARY

Accordingly, the inventors of the present disclosure have invented a display apparatus that resolves spot defects caused by the nonuniformity of the luminous wavelength distribution of a main light-emitting element and a redundancy light-emitting element within a dual chip, and a poor viewing angle due to a difference in left and right brightness.

Implementations of the present disclosure are directed to providing a display apparatus that improves a poor viewing angle due to a difference in left and right brightness of a main light-emitting element and a redundancy light-emitting element within a dual chip and uniformly distributes a luminous wavelength without being biased to one side so that left and right brightness and (in-plane) luminous wavelength distribution are uniform.

Objects of the present disclosure are not limited to the above-described objects, and other objects and advantages of the present disclosure that are not mentioned above can be understood by the following description and more clearly understood by implementations of the present disclosure. In addition, the objects and advantages of the present disclosure can be achieved by devices and combinations thereof that are described in the claims.

In a display apparatus according to one implementation of the present disclosure, brightness can be distributed uniformly within one pixel by arranging a redundancy light-emitting element in an inverted manner with respect to a main light-emitting element and differently forming mesa angles of light-emitting layers of each of the main light-emitting element and the redundancy light-emitting element.

According to the implementations of the present disclosure, by arranging the redundancy light-emitting element with respect to the main light-emitting element in the inverted manner, the luminous wavelength can be uniformly distributed without being biased to one side, thereby uniformly distributing brightness and a wavelength.

In addition, according to the implementations of the present disclosure, by arranging the redundancy light-emitting element corresponding to the main light-emitting element in the inverted manner, it is possible to improve the poor viewing angle due to the difference in left and right brightness and the spot defects due to the nonuniformity of the luminous wavelength.

In addition, according to the implementations of the present disclosure, by arranging the main light-emitting element and the redundancy light-emitting element as a dual chip, it is possible to improve the block-specific yield for the use of the chip on wafer CoW.

In addition, according to the implementations of the present disclosure, by arranging the redundancy light-emitting element with respect to the main light-emitting element in the inverted manner within one pixel, it is possible to improve the wavelength uniformity of the wafer CoW to about 1 nanometer (nm).

In addition, according to the implementations of the present disclosure, by chip-mixing the main light-emitting element and the redundancy light-emitting element, it is possible to improve the brightness defect within each pixel.

In addition, according to the implementations of the present disclosure, it is possible to improve the brightness defect within each pixel, thereby achieving the improvement in the quality of the display apparatus.

In addition, according to the implementations of the present disclosure, it is possible to improve the brightness defect within each pixel, thereby preventing a reduction in lifetime of the panel.

In addition, according to the implementations of the present disclosure, by uniformly distributing the brightness and the luminous wavelength within each pixel, it is possible to provide the long-lifetime and low-power display apparatus.

Effects of the present disclosure are not limited to the above-described effects, and other effects that are not described will be able to be clearly understood by those skilled in the art based on the following description.

Specific effects of the present disclosure along with the above-described effects are described along with the description of the following detailed matters for carrying out implementations of the disclosure.

### BRIEF DESCRIPTION OF THE SEVERAL VIEWS OF THE DRAWINGS

FIG. 1 is a plan view showing an example of a display apparatus according to an implementation of the present disclosure.

FIG. 2 is a view showing an example in which redundancy elements for second and third sub-elements are inverted in the display apparatus according to the implementation of the present disclosure.

FIG. 3 is a view showing an example in which all redundancy elements for the first to third sub-elements are inverted in the display apparatus according to the implementation of the present disclosure.

FIG. 4 is a view showing an example in which redundancy elements for a plurality of second and third sub-elements are inverted in the display apparatus according to the implementation of the present disclosure.

FIG. 5 is a view showing an example in which sub-elements of different colors are transferred onto a wafer according to the implementation of the present disclosure.

FIG. 6 is a view showing an example in which a plurality of sub-elements are transferred onto a donor part according to the implementation of the present disclosure.

FIG. 7 is a wiring diagram showing an example in which electrodes of sub-elements are disposed along with wiring according to the implementation of the present disclosure.

FIG. 8 is a view showing an example in which luminous wavelength distribution is mixed to achieve uniformity when chips on a wafer are transferred onto a main donor part and a redundancy donor part according to the implementation of the present disclosure.

FIG. 9 is a view showing a structure of one light-emitting diode (LED) chip according to the implementation of the present disclosure.

FIG. 10 is a view showing positions of LED chips on a wafer according to the implementation of the present disclosure.

FIG. 11 is a cross-sectional view of an LED chip along line A-A′ in FIG. 9 according to the implementation of the present disclosure.

FIG. 12 is a cross-sectional view showing a cross-sectional structure of a main chip and an inverted redundancy chip according to the implementation of the present disclosure.

FIG. 13 is a view showing the light emission of the main chip and the redundancy chip according to the implementation of the present disclosure.

FIG. 14 is a view showing an arrangement relationship of the main chip and the redundancy chip according to the implementation of the present disclosure.

### DETAILED DESCRIPTION

Advantages and features of the present disclosure and methods for achieving them will become clear with reference to implementations described below in detail in conjunction with the accompanying drawings. However, the present disclosure is not limited to implementations to be disclosed below but may be implemented in various different forms, these implementations are merely provided to make the disclosure of the present disclosure complete and fully inform those skilled in the art to which the present disclosure pertains of the scope of the present disclosure, and the present disclosure is only defined by the scope of the appended claims.

Since shapes, sizes, ratios, angles, numbers, etc., disclosed in the drawings for describing the implementations of the present disclosure are exemplary, the present disclosure is not limited to the illustrated items. The same reference number denotes the same components throughout the disclosure. In addition, in describing the present disclosure, when it is determined that the detailed description of a related known technology may unnecessarily obscure the gist of the present disclosure, the detailed description thereof will be omitted. When “comprises,” “has,” “consists of,” etc., described in the present disclosure are used, other parts may be added unless “only” is used. When a component is expressed in a singular form, it includes a case in which the component is provided as a plurality of components unless specifically stated otherwise.

In construing a component, the component is construed as including a margin of error even when there is no separate explicit description related to the margin of error.

When the positional relationship is described, for example, when the positional relationship between two parts is described using “on,” “above,” “under,” “next to,” or the like, one or more other parts may be located between the two parts unless “immediately” or “directly” is used.

When the temporal relationship is described, when the temporal relationship is described using the term “after,” “subsequently,” “then,” “before,” or the like, it may also include a non-consecutive case unless the term “immediately” or “directly” is used.

Although terms such as first and second are used to describe various components, these components are not limited by these terms. These terms are only used to distinguish one component from another component. Accordingly, a first component described below may be a second component within the technical spirit of the present disclosure.

In the description of the components of the present disclosure, terms such as A, B, (a), (b), etc., may be used. These terms are only for the purpose of distinguishing one component from another component, and the nature, sequence, order, or the like of the corresponding component is not limited by these terms. When a certain component is described as being “connected,” “coupled,” or “joined” to another component, the certain component may be connected or joined directly to another component, but it should be understood that other components may be “interposed” between the components, which may be connected or coupled indirectly, unless otherwise stated specially.

It should be understood that the term “at least one” includes any combination of one or more of associated components. For example, the term “at least one of first, second, and third components” may include not only the first, second, or third component, but also any combination of two or more of the first, second, and third components.

In the present disclosure, an “apparatus” may include a display apparatus including a display panel and a driving unit for driving the display panel. In addition, the apparatus may also include a set electronic apparatus or a set apparatus such as a laptop computer, a television, a computer monitor, a vehicle or automotive apparatus, or a mobile electronic apparatus such as a smartphone, an electronic pad, etc., which is a complete product or final product including a module and the like.

Accordingly, an apparatus in the present disclosure may include both a display apparatus and a set apparatus that is an application product or an end-user apparatus.

In addition, in some implementations, a module composed of a display panel, a driving unit, etc., may be referred to as a “display apparatus,” and an electronic apparatus as a finished product including a module may be separately referred to as a “set apparatus.” For example, the display apparatus may include a display panel and a source printed circuit board (PCB) that is a control unit for driving the display panel. The set apparatus may further include a set PCB that is a set control unit electrically connected to the source PCB to drive the entirety of the set apparatus.

A display panel used in implementations of the present disclosure is not limited to the shape or size of the display panel.

The respective features of various implementations of the present disclosure may be coupled or combined partially or entirely, various technological interworking and driving are made possible, and the implementations may be implemented independently of each other or implemented together in an associated relationship.

Hereinafter, implementations of the present disclosure will be described with reference to the accompanying drawings and implementations as follows. Scales of components illustrated in the drawings differ from the actual scale for convenience of description and, thus, are not limited to the scales illustrated in the drawings.

Hereinafter, as one implementation of the present disclosure, a display apparatus using a micro light-emitting diode (LED) as a light-emitting element will be described.

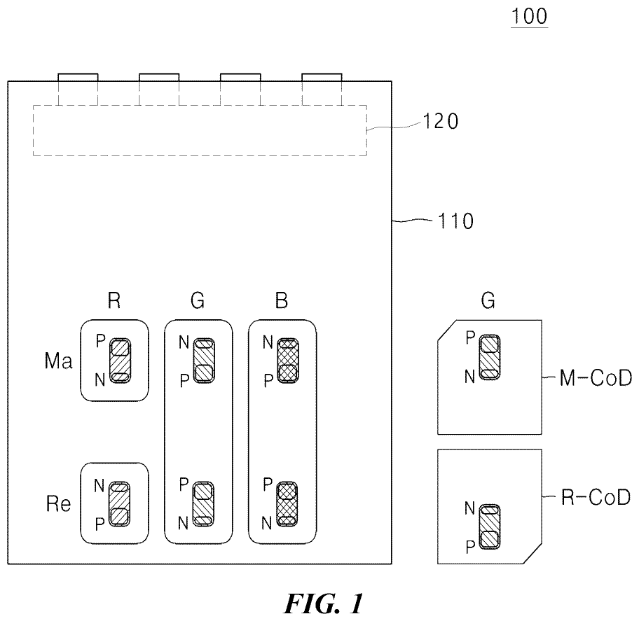

FIG. 1 is a plan view showing an example of a display apparatus according to an implementation of the present disclosure.

Referring to FIG. 1, a display apparatus 100 according to the implementation of the present disclosure may include a display panel 110 in which a main light-emitting element Ma and a redundancy light-emitting element Re are disposed in each color R, G, or B.

Each of the main light-emitting element Ma and the redundancy light-emitting element Re may have a form of a chip. Each of the main light-emitting element Ma and the redundancy light-emitting element Re may be, for example, a flat rectangular chip. In the following description, the main light-emitting element Ma may be referred to as a “main element Ma” or a “main chip Ma,” and the redundancy light-emitting element Re may be referred to as a “redundancy element Re” or a “redundancy chip Re.” In addition, in the implementation of the present disclosure, the main light-emitting element Ma may be referred to as a main light-emitting element M-Chip or a main chip Ma-Chip, and the redundancy light-emitting element Re may be referred to as a redundancy light-emitting element R-Chip or a redundancy chip Re-Chip.

The main element Ma may include a first electrode and a second electrode. The first electrode may be a P-type electrode including a P-type semiconductor material. The second electrode may be an N-type electrode including an N-type semiconductor material. In addition, the first electrode may be an N-type electrode including an N-type semiconductor material. The second electrode may be a P-type electrode including a P-type semiconductor material.

The main element Ma may further include a first light-emitting layer EL1. The main element Ma may be configured such that the first electrode P or N and the second electrode N or P face each other and are respectively disposed at the top and the bottom of the first light-emitting layer EL1.

The first light-emitting layer EL1 may include an inorganic material. The first light-emitting layer EL1 mainly uses a group III-V nitride semiconductor material, but is not limited thereto.

The first light-emitting layer EL1 may be a layer in which injected electrons and holes are combined to emit light. Although not shown, the first light-emitting layer EL1 may have a multi-quantum-well (MQW) structure. The MQW structure of the first light-emitting layer EL1 is formed by alternating a plurality of barrier layers and well layers, and the well layers are formed of InGaN layers and the barrier layers are formed of GaN, but the implementations of the present disclosure are not limited thereto.

Although not shown, the main element Ma may include an undoped GaN layer, an n-type GaN layer disposed on the GaN layer, the first light-emitting layer EL1 having the MQW structure and disposed on the n-type GaN layer, a p-type GaN layer disposed on the first light-emitting layer EL1, an ohmic contact layer formed of a transparent conductive material and disposed on the p-type GaN layer, a first electrode (a p-type electrode) in contact with a portion of the ohmic contact layer, and a second electrode (an n-type electrode) in contact with a portion of the n-type GaN layer exposed by etching portions of the first light-emitting layer EL1, the p-type GaN layer, and the ohmic contact layer.

The n-type GaN layer is a layer for supplying electrons to the first light-emitting layer EL1 and is formed by doping the GaN semiconductor layer with an n-type impurity such as Si.

The p-type GaN layer is a layer for injecting holes to the first light-emitting layer EL1 and is formed by doping the GaN semiconductor layer with a p-type impurity such as Mg, Zn, or Be.

The ohmic contact layer makes ohmic contact between the p-type GaN layer and the p-type electrode, and a transparent metal oxide such as indium tin oxide (ITO), indium gallium zinc oxide (IGZO), or indium zinc oxide (IZO) may be used.

The first electrode (the p-type electrode) and the second electrode (the n-type electrode) may be formed of a single layer or multiple layers formed of at least one of Ni, Au, Pt, Ti, Al, and Cr, or an alloy thereof.

In the case of the main element Ma, when voltage is applied to the first electrode (the p-type electrode) and the second electrode (the n-type electrode) and electrons and holes are injected from the n-type GaN layer and the p-type GaN layer into the first light-emitting layer EL1, respectively, excitons are generated in the first light-emitting layer EL1, and as these excitons decay, light corresponding to an energy difference between a lowest unoccupied molecular orbital (LUMO) and a highest occupied molecular orbital (HOMO) of the first light-emitting layer EL1 is generated and emitted to the outside.

At this time, a wavelength of the light emitted from the main element Ma may be controlled by controlling a thickness of the barrier layer of the MQW structure of the first light-emitting layer EL1.

The redundancy element Re may be disposed in a first direction (a vertical direction) on a plane to correspond to the main light-emitting element Ma. Here, the first direction may be a vertical direction or a horizontal direction. In the implementation of the present disclosure, when the first direction is a vertical direction, the second direction may be a horizontal direction, and when the first direction is the horizontal direction, the second direction may be the vertical direction.

The redundancy element Re may include a third electrode and a fourth electrode. The third electrode may be a P-type electrode including a P-type semiconductor material. The fourth electrode may be an N-type electrode including an N-type semiconductor material. In addition, the third electrode may be an N-type electrode including an N-type semiconductor material. The fourth electrode may be a P-type electrode including a P-type semiconductor material.

The redundancy element Re may further include a second light-emitting layer EL2. The redundancy element Re may be configured such that the first electrode P or N and the second electrode N or P face each other and are respectively disposed at the top and bottom of the second light-emitting layer EL2.

The second light-emitting layer EL2 may include an inorganic material. The second light-emitting layer EL2 mainly uses a group III-V nitride semiconductor material, but is not limited thereto.

The second light-emitting layer EL2 may be a layer in which injected electrons and holes are combined to emit light. Although not shown, the second light-emitting layer EL2 may have a MQW structure. The MQW structure of the second light-emitting layer EL2 is formed by alternating a plurality of barrier layers and well layers, and the well layers are formed of InGaN layers and the barrier layers are formed of GaN, but the implementations of the present disclosure are not limited thereto.

Although not shown, the redundancy element Re may include an undoped GaN layer, an n-type GaN layer disposed on the GaN layer, the second light-emitting layer EL2 having the MQW structure and disposed on the n-type GaN layer, a p-type GaN layer disposed on the second light-emitting layer EL2, an ohmic contact layer formed of a transparent conductive material and disposed on the p-type GaN layer, a third electrode (a p-type electrode) in contact with a portion of the ohmic contact layer, and a fourth electrode (an n-type electrode) in contact with a portion of the n-type GaN layer exposed by etching portions of the second light-emitting layer EL2, the p-type GaN layer, and the ohmic contact layer.

The third electrode (the p-type electrode) and the fourth electrode (the n-type electrode) may be formed of a single layer or multiple layers formed of at least one of Ni, Au, Pt, Ti, Al, and Cr, or an alloy thereof.

In the case of the redundancy element Re, when voltage is applied to the third electrode (the p-type electrode) and the fourth electrode (the n-type electrode) and electrons and holes are injected from the n-type GaN layer and the p-type GaN layer into the second light-emitting layer EL2, respectively, excitons are generated in the first light-emitting layer EL2, and as these excitons decay, light corresponding to an energy difference between an LUMO and an HOMO of the second light-emitting layer EL2 is generated and emitted to the outside.

At this time, a wavelength of the light emitted from the redundancy element Re may be controlled by controlling a thickness of the barrier layer of the MQW structure of the second light-emitting layer EL2.

Each of the main element Ma and the redundancy element Re may include a micro LED. The micro LED may be formed to have a size of about 10 to 100 μm. Although not shown in the drawing, the micro LED may be manufactured by forming a buffer layer on a substrate and growing a GaN thin film on the buffer layer. In this case, sapphire, silicon (si), GaN, silicon carbide (SiC), gallium arsenide (GaAs), zinc oxide (ZnO), etc., may be used as the substrate for growing a GaN thin film. In the implementation of the present disclosure, a sapphire substrate is applied as a substrate for growing a GaN thin film, which will be described.

In addition, when the substrate for growing a GaN thin film is formed of a different material from the GaN substrate, AlN, GaN, etc., may be used to prevent a degradation of the quality due to lattice mismatch occurring when growing an n-type GaN layer, which is an epi layer, directly on a substrate.

The n-type GaN layer may be formed by growing an undoped GaN layer and then doping the undoped thin film with an n-type impurity such as Si. In addition, the p-type GaN layer may be formed by growing an undoped GaN thin film and then doping the undoped thin film with a p-type impurity such as Mg, Zn, or Be.

The first electrode and the second electrode may be arranged in the first direction (the vertical direction) on the first light-emitting layer EL1, and the third electrode and the fourth electrode may be arranged on the second light-emitting layer EL2 in an inverted manner with respect to the first electrode and the second electrode in the first direction (the vertical direction).

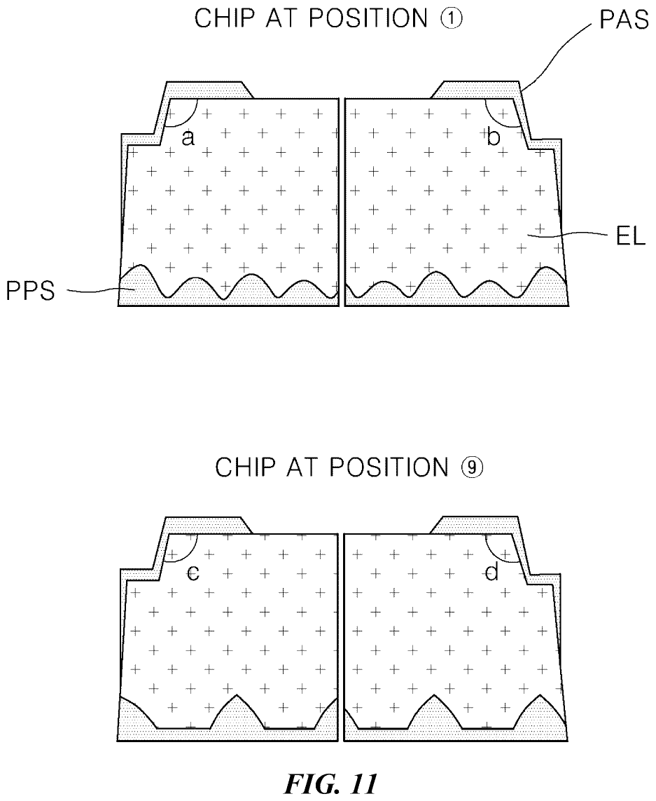

Each of the first light-emitting layer EL1 and the second light-emitting layer EL2 may have a mesa structure as shown in FIG. 11. The mesa structure has a raised hill shape, but has a structure in which an upper surface is a flat surface shape and two ends are milled and have a slanted cliff shape. In the implementation of the present disclosure, an angle that is slanted like a cliff from the flat upper surface on two ends is referred to as a “mesa angle.”

The second light-emitting layer EL2 of the redundancy element Re may be formed at a mesa angle different from a mesa angle of the first light-emitting layer EL1 of the main element Ma.

In the redundancy element Re, the third electrode and the fourth electrode may be arranged on the second light-emitting layer EL2 after being rotated 180 degrees in the first direction with respect to the first electrode and the second electrode.

The first electrode and the second electrode of the main element Ma may be formed of the same material, but are not limited thereto, and may be formed of different materials.

The third electrode and the fourth electrode of the redundancy element Re may be formed of the same material, but are not limited thereto, and may be formed of different materials.

The first electrode and the third electrode may be formed of the same material, and the second electrode and the fourth electrode may be formed of the same material.

In FIG. 1, each of the main element Ma and the redundancy element Re may include a first sub-element that emits light of a first color, a second sub-element that emits light of a second color, and a third sub-element that emits light of a third color. Each of the main element Ma and the redundancy element Re may further include a fourth sub-element that emits light of a fourth color.

For example, when the first color is red, the second color may be green, the third color may be blue, and the fourth color may be white. Each of the first color, the second color, the third color, and the fourth color may be one of red (R), green (G), blue (B), and white (W).

Each of the main element Ma and the redundancy element Re may have one or more sub-elements G transferred onto the display panel 110 through donor parts (chip on donor) M-CoD and R-CoD. For example, at the lower right of FIG. 1, the second sub-element G of the main element Ma may be transferred through the main donor part M-CoD, and the second sub-element G of the redundancy element Re can be transferred through the redundancy donor part R-CoD. In this case, the redundancy donor part R-CoD on which the second sub-element G of the redundancy element Re is disposed is positioned after being inverted (rotated) 180 degrees (°) in the first direction (the vertical direction) with respect to the main donor part M-CoD.

Accordingly, the second sub-element G of the main element Ma is configured such that the first electrode P and the second electrode N are sequentially arranged in the first direction (the vertical direction), and the second sub-element G of the redundancy element Re is configured such that the second electrode N and the first electrode P are sequentially arranged in the first direction (the vertical direction). Here, the donor part CoD may be referred to as a donor substrate.

In FIG. 1, the first electrode P and the second electrode N may have the same height (thickness) when disposed on the first light-emitting layer EL1 or have different heights (thicknesses). In addition, an upper surface of the first electrode P may be higher or lower than an upper surface of the second electrode N on the first light-emitting layer EL1.

In FIG. 1, the third electrode P and the fourth electrode N may have the same height (thickness) or have different heights (thicknesses) when disposed on the second light-emitting layer EL2. In addition, an upper surface of the third electrode P may be higher or lower than an upper surface of the fourth electrode N on the second light-emitting layer EL2.

In FIG. 1, a source PCB 120 is bent (folded backward) in a rear direction at an upper end of the display panel 110 and positioned on a rear surface of the display panel 110. The source PCB 120 may be referred to as the source PCB 120.

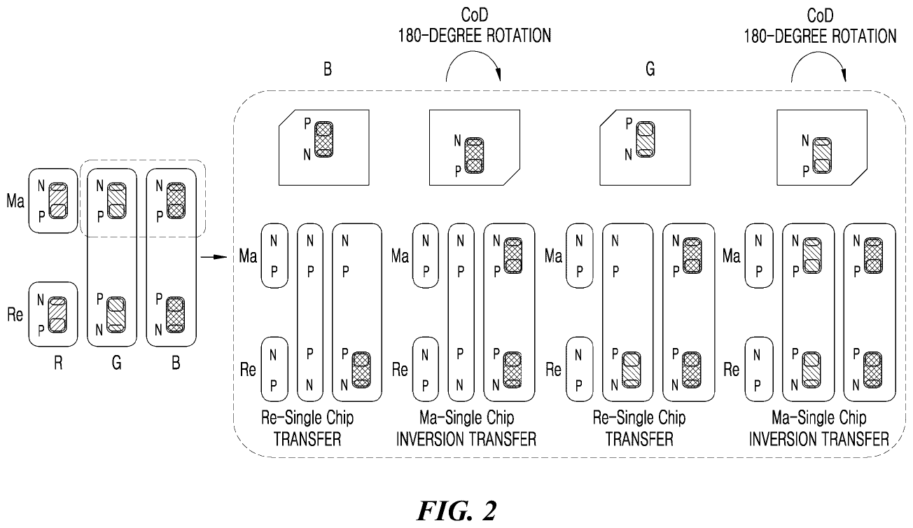

FIG. 2 is a view showing an example in which redundancy elements for second and third sub-elements are inverted in the display apparatus according to the implementation of the present disclosure.

Referring to the main element Ma and the redundancy element Re of the left of FIG. 2, the display apparatus according to the implementation of the present disclosure may have the second sub-element G and the third sub-element B of the redundancy element Re arranged after being inverted (rotated) 180 degrees (°) with respect to the first sub-element R, the second sub-element G, and the third sub-element B of the main element Ma.

In this case, the first sub-element R of the redundancy element Re may be disposed to correspond to the first sub-element R of the main element Ma so as to have the same polarity arrangement as the first sub-element R of the main element Ma without being inverted 180 degrees (°).

The first sub-element R may be configured such that the first electrode N and the second electrode P of the main element Ma are arranged in the first direction (the vertical direction) on the first light-emitting layer EL1 and the third electrode N and the fourth electrode P of the redundancy element Re are arranged in the first direction (the vertical direction) to have the same polarity arrangement as the first electrode N and the second electrode P on the second light-emitting layer EL2.

The second sub-element G and the third sub-element B may be configured such that the first electrode N and the second electrode P of the main element Ma are arranged in the first direction (the vertical direction) on the first light-emitting layer EL1 and the third electrode P and the fourth electrode N are arranged after being inverted (rotated) in the first direction (the vertical direction) to have the opposite polarity arrangement with respect to the first electrode N and the second electrode P on the second light-emitting layer EL2.

To have the above configuration, the display apparatus is subjected to the transfer process, for example, as shown at the right side of FIG. 2. The display apparatus may be subjected to a single chip transfer process through the redundancy donor part R-CoD so that the first electrode P and the second electrode N are sequentially arranged in the first direction (the vertical direction) with respect to the third sub-element B of the redundancy element Re. Hereinafter, the description of the transfer process will be omitted because it is a known technology, and only matters related to the implementations of the present disclosure will be described. For example, the main chip and the redundancy chip may be briefly described as being transferred using the wafer CoW or through the main donor part M-CoD or the redundancy donor part R-CoD.

Next, the display apparatus may be subjected to a single chip inversion transfer process after the main donor part M-CoD is rotated 180 degrees (°) in the first direction (the vertical direction) so that the second electrode N and the first electrode P are sequentially arranged in the first direction (the vertical direction) with respect to the third sub-element B of the main element Ma.

Subsequently, the display apparatus may be subjected to a single chip transfer process through the redundancy donor part R-CoD so that the first electrode P and the second electrode N are sequentially arranged in the first direction (the vertical direction) with respect to the second sub-element G of the redundancy element Re.

Subsequently, the display apparatus may be subjected to a single chip inversion transfer process after the main donor part M-CoD is rotated 180 degrees (°) in the first direction (the vertical direction) so that the second electrode N and the first electrode P are sequentially arranged in the first direction (the vertical direction) with respect to the second sub-element G of the main element Ma.

As described above, in the case of the second sub-element G and the third sub-element B, an example in which the second sub-element G is transferred after the third sub-element B is first transferred has been described as shown in FIG. 2, but the implementations of the present disclosure are not limited thereto, and the third sub-element B may be transferred after the second sub-element G may be first transferred.

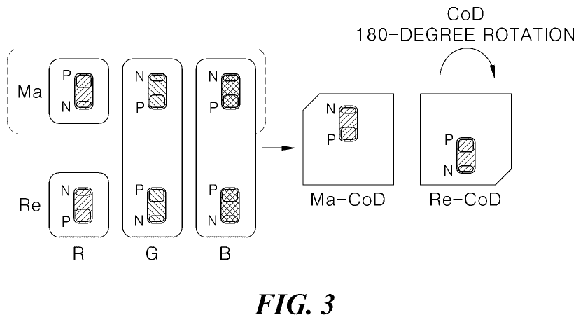

FIG. 3 is a view showing an example in which all redundancy elements for the first to third sub-elements are inverted in the display apparatus according to the implementation of the present disclosure.

Referring to FIG. 3, in the display apparatus according to the implementation of the present disclosure, all of the first sub-element R, the second sub-element G, and the third sub-element B of the redundancy element Re may be arranged after being inverted (rotated) 180 degrees (°) with respect to the first sub-element R, the second sub-element G, and the third sub-element B of the main element Ma.

For example, the first sub-element R may be configured such that the first electrode P and the second electrode N of the main element Ma are arranged in the first direction (the vertical direction) on the first light-emitting layer EL1 and the third electrode P and the fourth electrode N of the redundancy element Re, which have the same polarity direction, are arranged after being inverted (rotated) 180 degrees (°) in the first direction (the vertical direction) to have the opposite polarity directions to the first electrode P and the second electrode N on the second light-emitting layer EL2.

Each of the second sub-element G and the third sub-element B may be configured such that the first electrode N and the second electrode P are arranged in the first direction (the vertical direction) on the first light-emitting layer EL1 and the third electrode N and the fourth electrode P of the redundancy element Re, which have the same polarity direction, are arranged after being inverted (rotated) 180 degrees (°) in the first direction (the vertical direction) with respect to the first electrode N and the second electrode P on the second light-emitting layer EL2.

Even in this case, the redundancy element Re may be rotated and transferred through the redundancy donor part Re-CoD. For example, as shown on the right side of FIG. 3, the redundancy element Re of the second sub-element G has the fourth electrode P and the third electrode N sequentially arranged in the first direction (the vertical direction) after the redundancy donor part Re-CoD on which the redundancy element Re configured such that the third electrode N and the fourth electrode P with the same polarity direction are sequentially arranged in the first direction (the vertical direction) is seated is rotated 180 degrees (°) with respect to the main donor part Ma-CoD on which the main element Ma configured such that the first electrode N and the second electrode P are arranged in the first direction (the vertical direction) is disposed.

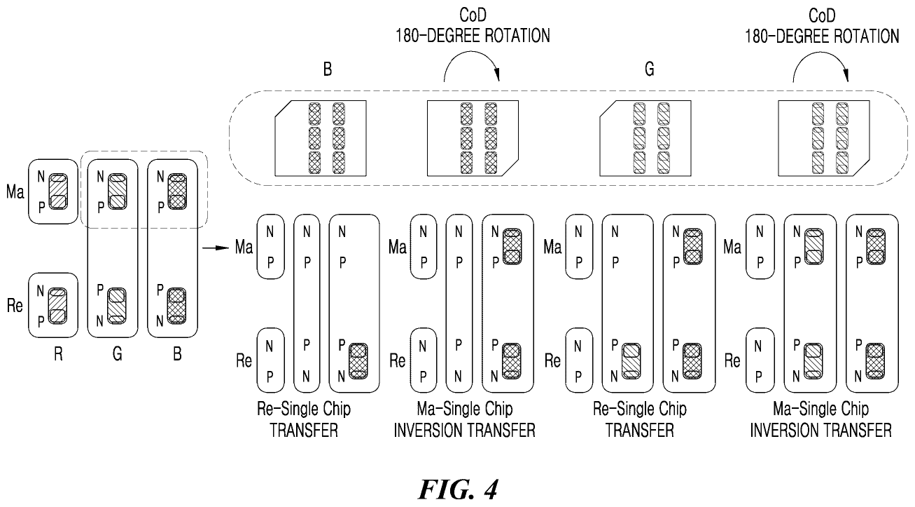

FIG. 4 is a view showing an example in which redundancy elements for a plurality of second and third sub-elements are inverted in the display apparatus according to the implementation of the present disclosure.

Referring to FIG. 4, in the display apparatus according to the implementation of the present disclosure, a plurality of second sub-elements G and the third sub-elements B of the redundancy element Re may be arranged after being rotated 180 degrees (°) with respect to the first sub-element R, the second sub-element G, and the third sub-element B of the main element Ma.

In this case, the first sub-element R of the redundancy element Re may be disposed to correspond to the first sub-element R of the main element Ma so that the first electrode N and the second electrode P are not inverted 180 degrees (°) and have the same polarity arrangement as the first sub-element R of the main element Ma.

The first sub-element R may be configured such that the first electrode N and the second electrode P of the main element Ma are arranged in the first direction (the vertical direction) and the third electrode N and the fourth electrode P of the redundancy element Re are arranged in the first direction so as to have the same polarity arrangement as the first electrode N and the second electrode P.

However, each of the second sub-element G and the third sub-element B may be configured such that the first electrode N and the second electrode P of the main element Ma are arranged in the first direction (the vertical direction) and the third electrode N and the fourth electrode P of the redundancy element Re, which have the same polarity direction, are arranged after being rotated 180 degrees (°) in the first direction (the vertical direction) to have the opposite polarity arrangement with respect to the first electrode N and the second electrode P.

As shown at the right side of FIG. 4, the display apparatus having such a configuration may be subjected to a single chip transfer process through the redundancy donor part R-CoD so that the first electrode P and the second electrode N are sequentially arranged in the first direction (the vertical direction) with respect to the plurality of third sub-elements B of the redundancy element Re on the wafer CoW.

Subsequently, the display apparatus may be subjected to a single chip inversion transfer process after the main donor part M-CoD is rotated 180 degrees (°) in the first direction (the vertical direction) so that the second electrode N and the first electrode P are sequentially arranged in the first direction (the vertical direction) with respect to the plurality of third sub-element B of the main element Ma.

Subsequently, the display apparatus may be subjected to a single chip transfer process through the redundancy donor part R-CoD so that the first electrode P and the second electrode N are sequentially arranged in the first direction (the vertical direction) with respect to a plurality of second sub-elements G of the redundancy element Re.

Subsequently, the display apparatus may be subjected to a single chip inversion transfer process after the main donor part M-CoD is rotated 180 degrees (°) in the first direction (the vertical direction) so that the second electrode N and the first electrode P are sequentially arranged in the first direction (the vertical direction) with respect to the plurality of second sub-elements G of the main element Ma.

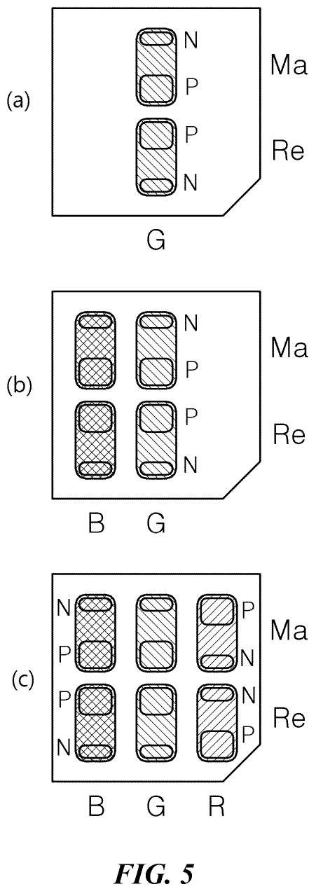

FIG. 5 is a view showing an example in which sub-elements of different colors are transferred onto a wafer according to the implementation of the present disclosure.

In FIG. 5, symbols of the same components as those shown in FIGS. 1 to 4 are omitted, and only symbols of the sub-elements R, G, and B are marked.

Referring to (A) of FIG. 5, the second sub-element G according to the implementation of the present disclosure may be disposed as a chip of the main element Ma and the redundancy element Re on one donor part.

The second sub-element G of the main element Ma may be configured such that the second electrode N is arranged at the top and the first electrode P is arranged at the bottom.

The second sub-element G of the redundancy element Re may be rotated 180 degrees (°) in the first direction (the vertical direction) with respect to the main element Ma so that the first electrode P may be arranged at the top and the second electrode N may be arranged at the bottom.

In (B) of FIG. 5, the third sub-element B and the second sub-element G may be disposed on a donor part positioned on a central portion.

The third sub-element B may have the main element Ma and the redundancy element Re disposed at the left side on the donor part, and the second sub-element G may have the main element Ma and the redundancy element Re disposed at the right side of the third sub-element B on the wafer.

The third sub-element B of the main element Ma may be configured such that the second electrode N is arranged at the top and the first electrode P is arranged at the bottom.

The third sub-element B of the redundancy element Re may be rotated 180 degrees (°) in the first direction (the vertical direction) with respect to the main element Ma so that the first electrode P may be arranged at the top and the second electrode N may be arranged at the bottom.

The second sub-element G of the main element Ma may be configured such that the second electrode N is arranged at the top and the first electrode P is arranged at the bottom.

The second sub-element G of the redundancy element Re may be rotated by 180 degrees (°) in the first direction (the vertical direction) with respect to the main element Ma so that the first electrode P may be arranged at the top and the second electrode N may be arranged at the bottom.

In (C) of FIG. 5, the third sub-element B, the second sub-element G, and the first sub-element R may be disposed on a donor part positioned at the bottom.

The third sub-element B may have the main element Ma and the redundancy element Re disposed vertically at the left side on the donor part, the second sub-element G may have the main element Ma and the redundancy element Re disposed vertically at the central portion on the wafer, and the first sub-element R may have the main element Ma and the redundancy element Re disposed vertically at the right side on the wafer.

The third sub-element B may be configured such that the first electrode N of the main element Ma is arranged at the top and the second electrode P is arranged at the bottom, and the redundancy element Re may be rotated 180 degrees (°) in the first direction (the vertical direction) with respect to the main element Ma so that the second electrode P may be arranged at the top and the first electrode N may be arranged at the bottom.

The second sub-element G may be configured such that the second electrode N of the main element Ma is arranged at the top and the first electrode P is arranged at the bottom, and the redundancy element Re may be rotated 180 degrees (°) in the first direction (the vertical direction) with respect to the main element Ma so that the first electrode P may be arranged at the top and the second electrode N may be arranged at the bottom.

The first sub-element R may be configured such that the first electrode P of the main element Ma is arranged at the top and the second electrode N is arranged at the bottom, and the redundancy element Re may be rotated 180 degrees (°) in the first direction (the vertical direction) with respect to the main element Ma so that the second electrode N may be arranged at the top and the first electrode P may be arranged at the bottom.

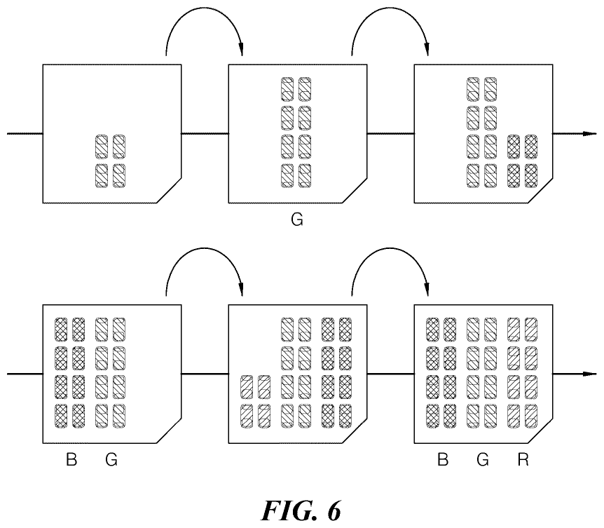

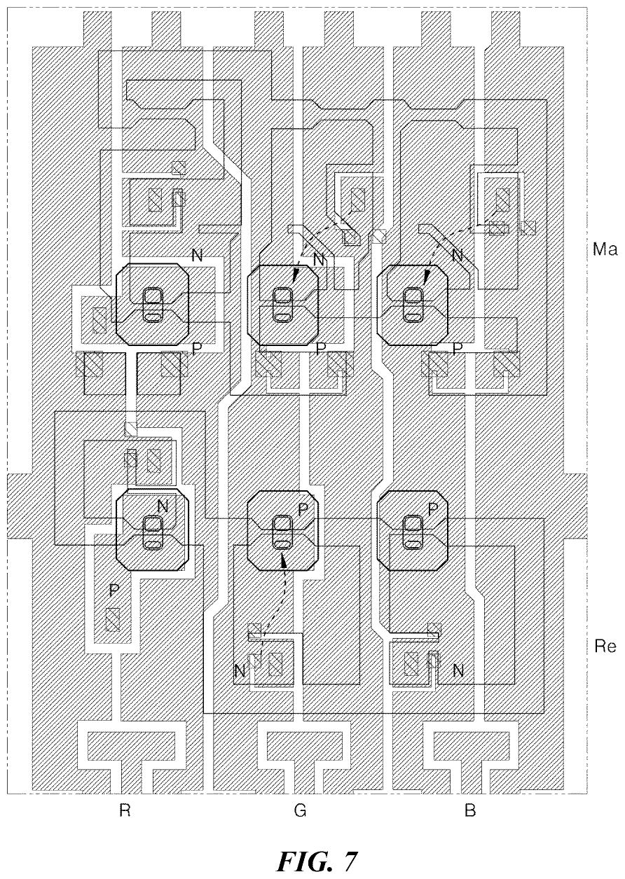

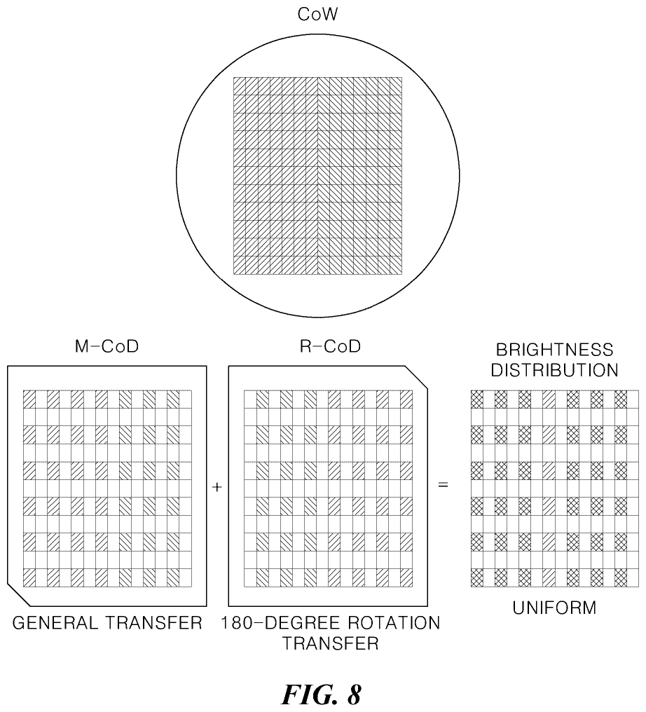

FIG. 6 is a view showing an example in which a plurality of sub-elements are transferred onto a donor part according to the implementation of the present disclosure. FIG. 7 is a wiring diagram showing an example in which electrodes of sub-elements are disposed along with wiring according to the implementation of the present disclosure. FIG. 8 is a view showing an example in which luminous wavelength distribution is mixed to achieve uniformity when chips on a wafer are transferred onto a main donor part and a redundancy donor part according to the implementation of the present disclosure.

Referring to FIG. 6, in the case of the sub-elements according to the implementation of the present disclosure, four or eight second sub-elements G may be, for example, transferred onto one donor part CoD.

When four second sub-elements G are transferred, two main elements Ma and two redundancy elements Re may be transferred. In this case, both the main element Ma and the redundancy element Re may be configured such that the first electrode P is arranged at the top and the second electrode N is arranged at the bottom.

When eight second sub-elements G are transferred, the remaining four second sub-elements G may be transferred upward from four second sub-elements G transferred previously and transferred after being rotated 180 degrees (°) in the first direction (the vertical direction) with respect to the four second sub-elements G transferred previously. In this case, all four second sub-elements G positioned upward may be configured such that the second electrode N is arranged at the top and the first electrode P is arranged at the bottom.

In addition, in the display apparatus, for example, four or eight third sub-elements B may be additionally transferred on the wafer on which eight second sub-elements G are transferred.

When four third sub-elements B are transferred, two main elements Ma and two redundancy elements Re may be transferred. In this case, both the main element Ma and the redundancy element Re may have the first electrode P arranged at the top and the second electrode N arranged at the bottom.

When eight third sub-elements B are transferred, the remaining four third sub-elements B may be transferred upward from four third sub-elements B transferred previously and transferred after being rotated 180 degrees (°) in the first direction (the vertical direction) with respect to the four third sub-elements B transferred previously. In this case, all four third sub-elements B positioned upward may be configured such that the second electrode N is arranged at the top and the first electrode P is arranged at the bottom.

In addition, in the display apparatus, for example, four or eight first sub-elements R may be additionally transferred on the wafer on which eight second sub-elements G are transferred and eight third sub-elements B are transferred.

When four first sub-elements R are transferred, two main elements Ma and two redundancy elements Re may be transferred. In this case, both the main element Ma and the redundancy element Re may be configured such that the second electrode N is arranged at the top and the first electrode P is arranged at the bottom.

When eight first sub-elements R are transferred, the remaining four first sub-elements R may be transferred upward from four first sub-elements R transferred previously and transferred after being rotated 180 degrees (°) in the first direction (the vertical direction) with respect to the four first sub-elements R transferred previously. In this case, all four first sub-elements R positioned upward may be configured such that the first electrode P is arranged at the top and the second electrode N is arranged at the bottom.

Referring to FIG. 7, the first sub-element R may be configured such that the second electrode N of the main element Ma is arranged at the top and the first electrode P is arranged at the bottom, and the redundancy element Re may be also configured such that the second electrode N is arranged at the top and the first electrode P is arranged at the bottom so as to have the same polarity direction as the main element.

Each of the second sub-element G and the third sub-element B may be configured such that the second electrode N of the main element Ma is arranged at the top and the first electrode P is arranged at the bottom.

However, the second sub-element G and the third sub-element B may be disposed after each of the redundancy elements Re are rotated 180 degrees (°) with respect to the main element Ma.

Accordingly, each of the second sub-element G and the third sub-element B may be configured such that the first electrode P is arranged at the top and the second electrode N is arranged at the bottom so that the electrodes of the redundancy element Re have the opposite polarity directions to those of the main element.

Referring to FIG. 8, a plurality of chips having left light-emitting wavelengths (leftward slashes) and a plurality of chips having right light-emitting wavelengths (rightward slashes) may be disposed on one wafer CoW.

In the case of the plurality of chips, a plurality of chips having the left light-emitting wavelength (the leftward slash) may be generally transferred on the main donor part M-CoD and a plurality of chips having the right light-emitting wavelength (the rightward slash) may be transferred on the redundancy donor part R-CoD after being rotated 180 degrees. Thereafter, the plurality of chips on the main donor part M-CoD and the redundancy donor part R-CoD are transferred onto the display panel by a transfer member.

Accordingly, a plurality of chips transferred onto the display panel have uniform luminous wavelength distribution and brightness distribution.

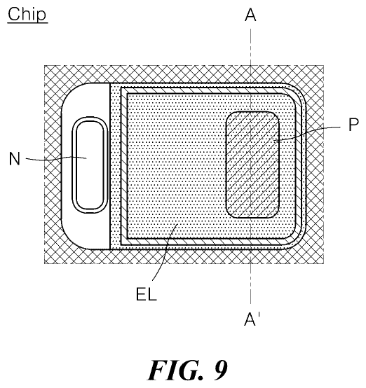

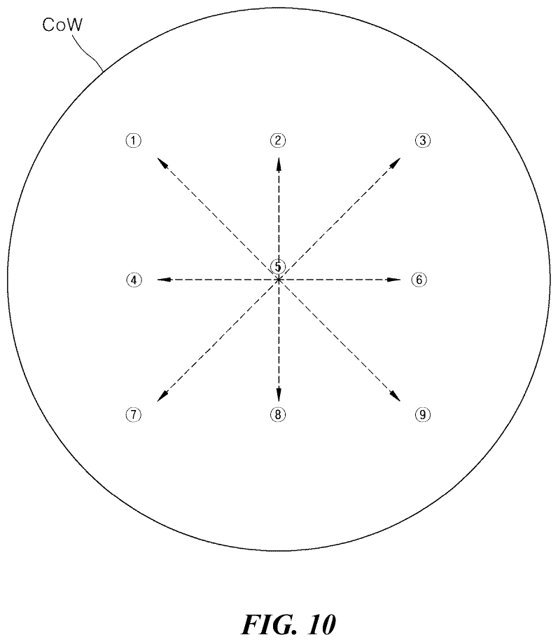

FIG. 9 is a view showing a structure of one light-emitting diode (LED) chip according to the implementation of the present disclosure. FIG. 10 is a view showing positions of LED chips on a wafer according to the implementation of the present disclosure. FIG. 11 is a cross-sectional view of an LED chip along line A-A′ in FIG. 9 according to the implementation of the present disclosure.

Referring to FIG. 9, one LED chip according to the implementation of the present disclosure may be configured such that the first electrode P is arranged at the right side and the second electrode N is arranged at the left side in the second direction (the horizontal direction).

Both the first electrode P and the second electrode N may be disposed on the light-emitting layer EL. The first electrode P and the second electrode N may be disposed to be spaced a predetermined distance from each other on the light-emitting layer EL.

Referring to FIG. 10, one LED chip having such a structure may be taken from one of a first position \textcircled{1} to a ninth position \textcircled{9} on the wafer CoW.

The first position \textcircled{1} is positioned in a northwest direction on the wafer CoW, a second position \textcircled{2} is positioned in a north direction on the wafer CoW, and a third position \textcircled{3} is positioned in a northeast direction on the wafer CoW.

A fourth position \textcircled{4} is positioned in a west direction on the wafer CoW, a fifth position \textcircled{5} is positioned at the exact center on the wafer CoW, and a sixth position \textcircled{6} is positioned in an east direction on the wafer CoW.

A seventh position \textcircled{7} is positioned in a southwest direction on the wafer CoW, an eighth position \textcircled{8} is positioned in a south direction on the wafer CoW, and the ninth position \textcircled{9} is positioned in a southeast direction on the wafer CoW.

Mesa angles (e.g., a left mesa angle and a right mesa angle) of the chip at each position on the wafer CoW of FIG. 10 is 72.7 degrees (°) and 69.0 degrees (°) at the first position \textcircled{1}, 70.6 degrees (°) and 72.1 degrees (°) at the second position \textcircled{2}, 77.2 degrees (°) and 74.4 degrees (°) at the third position \textcircled{3}, 71.6 degrees (°) and 71.6 degrees (°) at the fourth position \textcircled{4}, 76.0 degrees (°) and 74.5 degrees (°) at the fifth position \textcircled{5}, 77.2 degrees (°) and 76.3 degrees (°) at the sixth position \textcircled{6}, 71.0 degrees (°) and 71.0 degrees (°) at the seventh position \textcircled{7}, 74.5 degrees (°) and 72.6 degrees (°) at the eighth position \textcircled{8}, and 73.0 degrees (°) and 70.7 degrees (°) at the ninth position \textcircled{9}.

Referring to FIG. 11, an LED chip taken from the first position \textcircled{1} on the wafer CoW is configured such that the first light-emitting layer EL1 is disposed on a sapphire substrate PPS and a passivation layer PAS is disposed on two sides of an upper surface of the first light-emitting layer EL1 when viewed from a cross section of the first electrode P.

Hereinafter, in the cross-sectional views of FIGS. 11 to 13, the first electrode P is omitted and the structure of the first light-emitting layer EL1 is mainly shown.

In this case, mesa angles of the first light-emitting layer EL1 at two ends in the second direction (the horizontal direction) on the first electrode P side may be different. For example, at the first position \textcircled{1}, the mesa angles formed by two sides of the upper surface of the first light-emitting layer EL1 may be different, for example, 72.7 degrees (°) (Angle a) on one side and 69.0 degrees (°) (Angle b) on the other side.

Meanwhile, an LED chip taken from the ninth position \textcircled{9} on the wafer CoW is configured such that the second light-emitting layer EL2 is disposed on the sapphire substrate PPS and the passivation layer PAS is disposed on two sides of an upper surface of the second light-emitting layer EL2 when viewed from a cross-section of the third electrode P.

In this case, mesa angles of the second light-emitting layer EL2 at two ends in the second direction (the horizontal direction) on the third electrode P side may be different. For example, at the ninth position \textcircled{9}, the mesa angles formed by two sides of the upper surface of the second light-emitting layer EL2 may be different, for example 73.0 degrees (°) (Angle c) on one side and 70.7 degrees (°) (Angle d) on the other side.

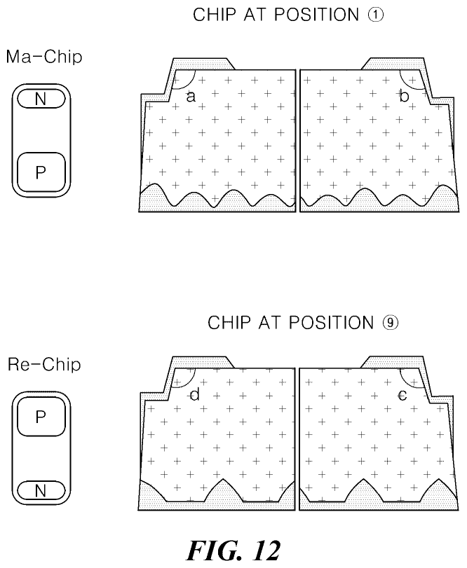

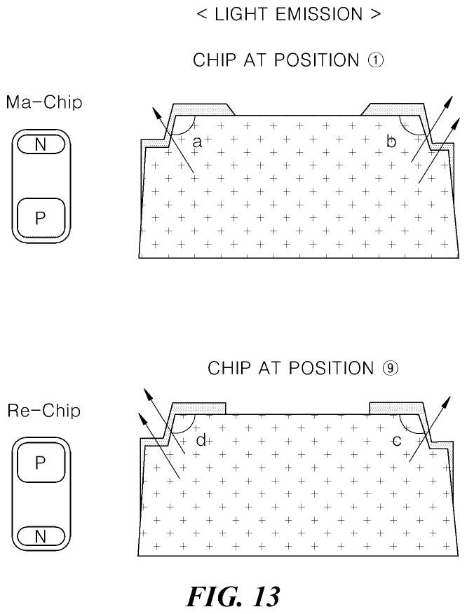

FIG. 12 is a cross-sectional view showing a cross-sectional structure of a main chip and an inverted redundancy chip according to the implementation of the present disclosure. FIG. 13 is a view showing the light emission of the main chip and the redundancy chip according to the implementation of the present disclosure.

Referring to FIG. 12, it can be seen that the main chip Ma-Chip according to the implementation of the present disclosure is a chip taken from the first position \textcircled{1} on the wafer, and the mesa angles formed by two sides of the upper surface of the first light-emitting layer EL1 are 72.7 degrees (°) (Angle a) and 69.0 degrees (°) (Angle b).

In contrast, it can be seen that, in the case of a redundancy chip Re-Chip rotated 180 degrees (°) with respect to the main chip Ma-Chip and brought from the ninth position \textcircled{9}, the mesa angles formed by two sides of the upper surface of the second light-emitting layer EL2 are 70.7 degrees (°) (Angle d) and 73.0 degrees (°) (Angle c).

The redundancy chip Re-Chip originally has the mesa angles of 73.0 degrees (°) (Angle c) and 70.7 degrees (°) (Angle d) when transferred to the ninth position \textcircled{9}, but when rotated 180 degrees (°) and transferred in an inverted manner, the mesa angles are changed to 70.7 degrees (°) (Angle d) and 73.0 degrees (°) (Angle c).

Accordingly, a difference (72.7−69.0=3.7°) in mesa angle between two ends of the first light-emitting layer EL1 on the first electrode P side may be greater than a difference (73.0−70.7=2.3°) in mesa angle between two ends of the second light-emitting layer EL2 on the third electrode P side.

Referring to FIG. 13, in the display apparatus according to the implementation of the present disclosure, a main chip Ma-Chip having mesa angles of 72.7 degrees (°) (Angle a) and 69.0 degrees (°) (Angle b) and a redundancy chip Re-Chip having mesa angles of 70.7 degrees (°) (Angle d) and 73.0 degrees (°) (Angle c) may be transferred.

The light-emitting layers EL1 and EL2 emit more light from the upper surface with a smaller mesa angle.

The first light-emitting layer EL1 may emit a greater amount of light at one end with a smaller mesa angle of 69.0° (Angle b) than at the other end with a larger mesa angle of 72.7° (Angle a) among the two ends in the second direction (the horizontal direction).

The second light-emitting layer EL2 may emit a greater amount of light at one end with a smaller mesa angle of 70.7° (Angle d) than at the other end with a larger mesa angle of 73.0° (Angle c) among the two ends in the second direction (the horizontal direction).

The main chip Ma-Chip emits a greater amount of light toward an upper-right surface with a smaller mesa angle of 69.0 degrees (°) (Angle b), and the redundancy chip Re-Chip emits a greater amount of light emitted toward an upper-left surface with a smaller mesa angle of 70.7 degrees (°) (Angle d).

In the main light-emitting element Ma-Chip and the redundancy light-emitting element Re-Chip, the amount of light emitted by the first light-emitting layer EL1 and the second light-emitting layer EL2 can be balanced without being biased to one side.

Accordingly, in the display apparatus according to the implementation of the present disclosure, light is uniformly emitted by the main chip Ma-Chip and the redundancy chip Re-Chip within one sub-pixel, and thus brightness can be distributed uniformly.

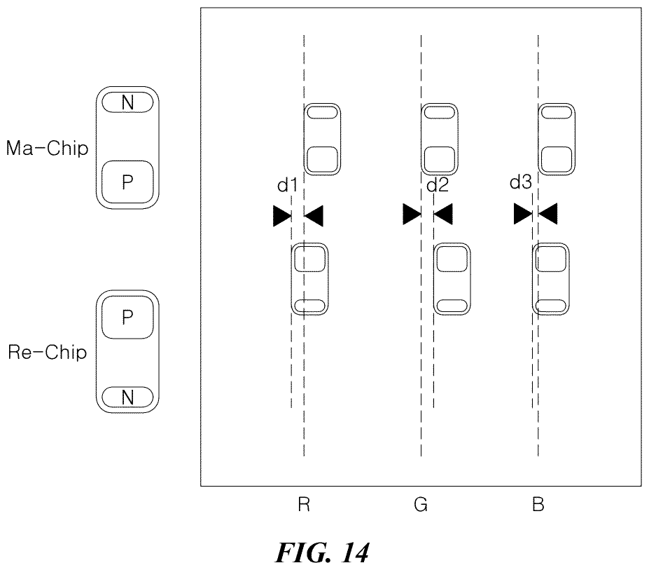

FIG. 14 is a view showing an arrangement relationship of the main chip and the redundancy chip according to the implementation of the present disclosure.

Referring to FIG. 14, in the case of the main light-emitting element Ma-Chip and the redundancy light-emitting element Re-Chip according to the implementation of the present disclosure, only the main light-emitting elements Ma-Chip may be transferred first, and the redundancy light-emitting elements Re-Chip may be then transferred. In this case, the redundancy light-emitting element Re-Chip may be disposed to correspond to the main light-emitting element Ma-Chip in the first direction (the vertical direction) in a plan view, but may be disposed at predetermined distances d1, d2, and d3 away from an axis in the first direction with respect to the main light-emitting element Ma-Chip.

In this case, the main chip Ma-Chip may be configured such that the first electrode P is arranged at the bottom and the second electrode N is arranged at the top, and the redundancy chip Re-Chip may be configured such that the first electrode P is arranged at the top and the second electrode N is arranged at the bottom.

The redundancy chip Re-Chip may be disposed to be spaced a first distance d1 leftward from the main chip Ma-Chip in the case of the first sub-element R, disposed to be spaced a second distance d2 right ward from the main chip Ma-Chip in the case of the second sub-element G, and disposed to be spaced a third distance d3 leftward from the main chip Ma-Chip in the case of the third sub-element B.

Here, all of the first distance d1, the second distance d2, and the third distance d3 may be the same.

The first distance d1, the second distance d2, and the third distance d3 may be different.

The first distance d1 and the second distance d2 may differ from the third distance d3. For example, the first distance d1 and the second distance d2 may be the same and may be larger than the third distance d3.

Meanwhile, each of the second sub-element G and the third sub-element B may have a larger size (volume) than the first sub-element R. For example, each of the second sub-element G and the third sub-element B may have a size (area) of 16.5 micrometers (μm) in width and 27 micrometers (μm) in height. The first sub-element R may have a size (area) of 16.0 micrometers (μm) in width and 27.0 micrometers (μm) in height.

Accordingly, each of the second sub-element G and the third sub-element B may include a light-emitting layer having a larger area than the light-emitting layer of the first sub-element R.

As described above, according to the implementation of the present disclosure, it is possible to implement a display apparatus in which a redundancy light-emitting element is disposed after being inverted with respect to a main light-emitting element, and mesa angles of light-emitting layers of the main light-emitting element and the redundancy light-emitting element are different.

A display apparatus according to implementations of the present disclosure may be described as follows.

According to an implementation of the present disclosure, there is provided a display apparatus including a main light-emitting element including a first light-emitting layer, a first electrode (P), and a second electrode (N), and a redundancy light-emitting element including a second light-emitting layer, a third electrode (P), and a fourth electrode (N), in which the redundancy light-emitting element may be arranged to correspond to the main light-emitting element in a first direction in a plan view, the first electrode and the second electrode may be arranged in the first direction on the first light-emitting layer, and the third electrode and the fourth electrode may be arranged after being inverted in the first direction with respect to the first electrode and the second electrode on the second light-emitting layer.

According to some implementations of the present disclosure, each of the first light-emitting layer and the second light-emitting layer may have a mesa structure, and the second light-emitting layer may be formed at a mesa angle different from a mesa angle of the first light-emitting layer.

According to some implementations of the present disclosure, mesa angles of two ends of the first light-emitting layer in a second direction on the first electrode side may be different.

According to some implementations of the present disclosure, mesa angles of two ends of the second light-emitting layer in the second direction on the third electrode side may be different.

According to some implementations of the present disclosure, a difference in mesa angle between the two ends of the first light-emitting layer on the first electrode side may be greater than a difference in mesa angle between the two ends of the second light-emitting layer on the third electrode side.

According to some implementations of the present disclosure, the first light-emitting layer may emit a greater amount of light at one end with a smaller mesa angle than at the other end with a larger mesa angle among the two ends in the second direction.

According to some implementations of the present disclosure, the second light-emitting layer may emit a greater amount of light at one end with a smaller mesa angle than at the other end with a larger mesa angle among the two ends in the second direction.

According to some implementations of the present disclosure, in the main light-emitting element and the redundancy light-emitting element, the amount of light emitted by the first light-emitting layer and the second light-emitting layer may be balanced without being biased to one side.

According to some implementations of the present disclosure, when the redundancy light-emitting element is disposed to correspond to the main light-emitting element in the first direction in a plan view, the redundancy light-emitting element may be disposed at a predetermined distance away from an axis in the first direction with respect to the main light-emitting element.

According to some implementations of the present disclosure, the third electrode and the fourth electrode may be arranged after being rotated 180 degrees in the first direction with respect to the first electrode and the second electrode on the second light-emitting layer.

According to some implementations of the present disclosure, the first electrode and the second electrode may be formed of different materials, and the third electrode and the fourth electrode may be formed of different materials.

According to some implementations of the present disclosure, the first electrode and the third electrode may be formed of the same material, and the second electrode and the fourth electrode may be formed of the same material.

According to some implementations of the present disclosure, each of the main light-emitting element and the redundancy light-emitting element may include a first sub-element that emits light of a first color, a second sub-element that emits light of a second color, and a third sub-element that emits light of a third color.

According to some implementations of the present disclosure, the first sub-element may be configured such that the first electrode and the second electrode are arranged on the first light-emitting layer in the first direction, the third electrode and the fourth electrode may be arranged in the first direction on the second light-emitting layer so as to have the same polarity arrangement as the first electrode and the second electrode, and each of the second sub-element and the third sub-element may be configured such that the first electrode and the second electrode may be arranged on the first light-emitting layer in the first direction and the third electrode and the fourth electrode may be arranged after being inverted in the first direction to have an opposite polarity arrangement to the first electrode and the second electrode on the second light-emitting layer.

According to some implementations of the present disclosure, each of the first sub-element, the second sub-element, and the third sub-element may be arranged such that the first electrode and the second electrode may be arranged in the first direction on the first light-emitting layer and the third electrode and the fourth electrode may be arranged after being inverted in the first direction with respect to the first electrode and the second electrode on the second light-emitting layer.

According to some implementations of the present disclosure, each of the second sub-element and the third sub-element may include a light-emitting layer having a larger area than a light-emitting layer of the first sub-element.

Although the present disclosure has been described above with reference to the exemplary drawings, the present disclosure is not limited by the implementations and drawings disclosed in the present disclosure, and it is apparent that various modifications can be made by those skilled in the art within the scope of the technical spirit of the present disclosure. In addition, even when the operational effects according to the configuration of the present disclosure have not been explicitly described in the description of the implementations of the present disclosure, it is apparent that the effects predictable by the corresponding configuration should also be recognized.

### DESCRIPTION OF REFERENCE NUMERALS

100: display apparatus
110: display panel
120: source PCB
Ma: main light-emitting element
Re: redundancy light-emitting element
P, N: electrodes
R, G, B: sub-elements
CoW: wafer
CoD: donor part
EL: light-emitting layer

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus, comprising:
a main light-emitting element including a first light-emitting layer, a first electrode, and a second electrode; and
a redundancy light-emitting element including a second light-emitting layer, a third electrode, and a fourth electrode,
wherein:
the redundancy light-emitting element is disposed to correspond to the main light-emitting element in a first direction in a plan view;
the first electrode and the second electrode are arranged on the first light-emitting layer in the first direction; and
the third electrode and the fourth electrode are disposed on the second light-emitting layer and are arranged inverted in the first direction with respect to the first electrode and the second electrode.

2. The display apparatus of claim 1, wherein:
each of the first light-emitting layer and the second light-emitting layer has a mesa structure; and
the second light-emitting layer is formed at a mesa angle different from a mesa angle of the first light-emitting layer.

3. The display apparatus of claim 2, wherein mesa angles of two ends of the first light-emitting layer in a second direction on the first electrode side are different.

4. The display apparatus of claim 3, wherein mesa angles of two ends of the second light-emitting layer in the second direction on the third electrode side are different.

5. The display apparatus of claim 4, wherein a difference in mesa angle between the two ends of the first light-emitting layer on the first electrode side is greater than a difference in mesa angle between the two ends of the second light-emitting layer on the third electrode side.

6. The display apparatus of claim 3, wherein the first light-emitting layer emits a greater amount of light at one end with a smaller mesa angle than at the other end with a larger mesa angle among the two ends in the second direction.

7. The display apparatus of claim 6, wherein the second light-emitting layer emits a greater amount of light at one end with a smaller mesa angle than at the other end with a larger mesa angle among the two ends in the second direction.

8. The display apparatus of claim 7, wherein in the main light-emitting element and the redundancy light-emitting element, the amount of light emitted by the first light-emitting layer and the second light-emitting layer are balanced without being biased to one side.

9. The display apparatus of claim 1, wherein, when the redundancy light-emitting element is disposed to correspond to the main light-emitting element in the first direction in a plan view, the redundancy light-emitting element is disposed at a predetermined distance away from an axis in the first direction with respect to the main light-emitting element.

10. The display apparatus of claim 1, wherein the third electrode and the fourth electrode are disposed on the second light-emitting layer, and are arranged and rotated 180 degrees in the first direction with respect to the first electrode and the second electrode.

11. The display apparatus of claim 1, wherein:
the first electrode and the second electrode are formed of different materials; and
the third electrode and the fourth electrode are formed of different materials.

12. The display apparatus of claim 1, wherein:
the first electrode and the third electrode are formed of the same material; and
the second electrode and the fourth electrode are formed of the same material.

13. The display apparatus of claim 1, wherein each of the main light-emitting element and the redundancy light-emitting element includes:
a first sub-element that emits light of a first color;
a second sub-element that emits light of a second color; and
a third sub-element that emits light of a third color.

14. The display apparatus of claim 13, wherein:
the first sub-element is configured such that the first electrode and the second electrode are arranged on the first light-emitting layer in the first direction, and the third electrode and the fourth electrode are arranged in the first direction on the second light-emitting layer so as to have the same polarity arrangement as the first electrode and the second electrode; and
each of the second sub-element and the third sub-element is configured such that the first electrode and the second electrode are arranged on the first light-emitting layer in the first direction and the third electrode and the fourth electrode are disposed on the second light-emitting layer and are arranged inverted in the first direction to have an opposite polarity arrangement to the first electrode and the second electrode.

15. The display apparatus of claim 13, wherein each of the first sub-element, the second sub-element, and the third sub-element is arranged such that the first electrode and the second electrode are arranged in the first direction on the first light-emitting layer and the third electrode and the fourth electrode are arranged on the second light-emitting layer and are arranged inverted in the first direction with respect to the first electrode and the second electrode.

16. The display apparatus of claim 13, wherein each of the second sub-element and the third sub-element includes a light-emitting layer having a larger area than a light-emitting layer of the first sub-element.
